(19) United States
(12) Patent Application Publication
(10) Pub. No.: US 2026/0090395 A1
(43) Pub. Date: Mar. 26, 2026

(54) SEMICONDUCTOR DEVICE

(71) Applicant: SK hynix Inc., Icheon-si Gyeonggi-do (KR)

(72) Inventor: Heon Yong CHANG, Icheon-si Gyeonggi-do (KR)

(73) Assignee: SK hynix Inc., Icheon-si Gyeonggi-do (KR)

(21) Appl. No.: 19/085,877

(22) Filed: Mar. 20, 2025

(30) Foreign Application Priority Data
Sep. 24, 2024 (KR) 10-2024-0129099

(51) Int. Cl. H01L 23/544; H01L 21/78; H10B 12/00

(52) U.S. Cl. CPC H10W 46/00; H10B 12/0335; H10P 54/00; H10W 46/503

(57) ABSTRACT

Provided herein is a semiconductor device. The semiconductor device includes a wafer extending in a plane in a first direction and a second direction, a first insulating layer, a second insulating layer, and a third insulating layer sequentially stacked in a third direction over a surface of the wafer, a plurality of lower vernier patterns disposed in the first insulating layer and the second insulating layer, and a plurality of dummy patterns disposed in the third insulating layer.

### CROSS-REFERENCE TO RELATED APPLICATION

The present application claims priority under 35 U.S. C. § 119(a) to Korean patent application number 10-2024-0129099 filed on Sep. 24, 2024 in the Korean Intellectual Property Office, the entire contents of which application is incorporated herein by reference.

### BACKGROUND

### 1. Technical Field

Various embodiments of the present disclosure generally relate to a semiconductor device, and more particularly to a semiconductor device including a scribe lane region and a chip region.

### 2. Related Art

A semiconductor device includes multilayer patterns that form an integrated circuit. Alignment between the multilayer patterns may be measured by inspecting an overlay mark.

The overlay mark is formed in a scribe lane region of a wafer. In the scribe lane region, various patterns that do not participate in the operation of the integrated circuit may be disposed in addition to the overlay mark.

As the semiconductor device becomes more highly integrated, the patterns forming the integrated circuit become more complex, leading to an increase in the patterns disposed in the scribe lane region.

### SUMMARY

An embodiment of the present disclosure may provide for a semiconductor device. The device may include a wafer including a chip region and a scribe lane region surrounding the chip region, a surface of the wafer extending in a plane in a first direction and a second direction, a first insulating layer, a second insulating layer, and a third insulating layer sequentially stacked in a third direction over the surface of the wafer, a first overlay mark including a plurality of lower vernier patterns disposed in the first insulating layer and the second insulating layer, and overlapping the scribe lane region of the wafer in the vertical direction, and a plurality of dummy patterns disposed in the third insulating layer, and overlapping the scribe lane region of the wafer in the third direction. Each of the plurality of dummy patterns is formed with a first area measured in the first and second directions and each of the plurality of lower vernier patterns is formed with a second area measured in the first and second directions. The first area of each of the plurality of dummy patterns is smaller than the second area of each of the plurality of lower vernier patterns.

An embodiment of the present disclosure may provide for a semiconductor device. The device may include a wafer including a chip region and a scribe lane region surrounding the chip region, a surface of the wafer extending in a plane in a first direction and a second direction, a first insulating layer, a second insulating layer, a third insulating layer, a fourth insulating layer, and a fifth insulating layer sequentially stacked in a third direction over the surface of the wafer, a plurality of dummy patterns disposed in the third insulating layer, and overlapping the scribe lane region in the third direction, and an overlay mark overlapping the scribe lane region of the wafer in the third direction. The overlay mark might not be disposed in a region within each of the fourth insulating layer and the fifth insulating layer overlapping the plurality of dummy patterns in the third direction. The overlay mark may include a plurality of lower vernier patterns disposed in the first insulating layer and the second insulating layer.

An embodiment of the present disclosure may provide for a semiconductor device. The device may include a wafer including a chip region and a scribe lane region surrounding the chip region, a surface of the wafer extending in a plane in a first direction and a second direction, a first insulating layer, a second insulating layer, and a third insulating layer sequentially stacked in a third direction over the surface of the wafer, an overlay mark including a plurality of lower vernier patterns disposed in the first insulating layer and the second insulating layer, and overlapping the scribe lane region of the wafer in the third direction, and a dishing inhibiting structure including a plurality of dummy patterns disposed in the third insulating layer, the plurality of dummy patterns overlapping the scribe lane region of the wafer in the third direction. The plurality of dummy patterns may overlap the plurality of lower vernier patterns in the third direction.

### BRIEF DESCRIPTION OF THE DRAWINGS

FIG. 1 is a plan view illustrating a wafer according to an embodiment of the present disclosure.

FIG. 2 is a sectional view of a semiconductor device according to an embodiment of the present disclosure taken along a chip region.

FIG. 3 is a plan view illustrating an overlay mark and a plurality of dummy patterns of the semiconductor device according to an embodiment of the present disclosure disposed in a scribe lane region.

FIGS. 4A, 4B, and 4C are sectional views of the semiconductor device according to an embodiment of the present disclosure taken along line A1-A1′, line B1-B1′, and line C1-C1′ shown in FIG. 3.

FIGS. 5A and 5B are sectional views illustrating a chip region and a scribe lane region of the semiconductor device according to an embodiment of the present disclosure.

FIG. 6 is a plan view illustrating an overlay mark and a plurality of dummy patterns of the semiconductor device according to an embodiment of the present disclosure disposed in the scribe lane region.

FIGS. 7A, 7B, and 7C are sectional views of the semiconductor device according to an embodiment of the present disclosure taken along line A2-A2′, line B2-B2′, and line C2-C2′ shown in FIG. 6.

FIG. 8 is a sectional view illustrating an overlay mark and multilayer dummy patterns of the semiconductor device according to an embodiment of the present disclosure disposed in the scribe lane region.

FIGS. 9A and 9B are plan views illustrating a first overlay mark according to an embodiment of the present disclosure.

FIGS. 10A, 10B, and 10C are plan views illustrating a plurality of dummy patterns and a second overlay mark according to an embodiment of the present disclosure.

FIG. 11 is a plan view illustrating a first overlay mark and a plurality of dummy patterns according to an embodiment of the present disclosure.

FIG. 12 is a plan view illustrating an insulating layer over a plurality of dummy patterns according to an embodiment of the present disclosure.

FIGS. 13A and 13B are plan views illustrating multilayer dummy patterns according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “over,” “lower,” “upper” and other terms implying relative spatial relationship or orientation are utilized only for the purpose of ease of description or reference to a drawing and are not otherwise limiting. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. The cross-hatching throughout the figures illustrates corresponding or similar areas between the figures rather than indicating the materials associated with the areas.

Various embodiments of the present disclosure are directed to a semiconductor device capable of increasing the pattern integration degree of a scribe lane region while ensuring the stability of a manufacturing process.

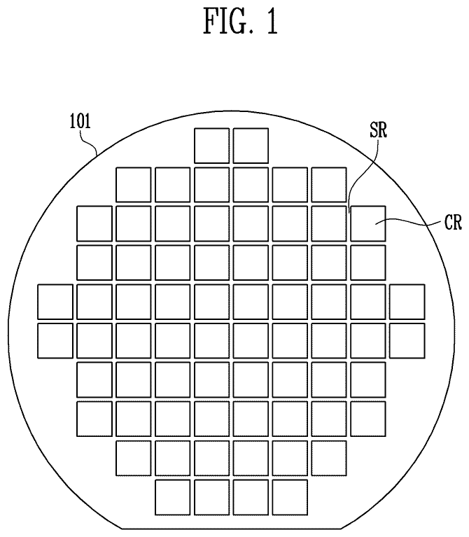

FIG. 1 is a plan view illustrating a wafer according to an embodiment of the present disclosure.

Referring to FIG. 1, in a planar view, the wafer 101 may include a plurality of chip regions CR and a scribe lane region SR. The wafer 101 may include a semiconductor substrate. In an embodiment, the wafer 101 may include silicon, germanium, or a mixture thereof. The wafer 101 may extend in a plane in a first direction and a second direction.

An integrated circuit of a semiconductor device may be disposed in each chip region CR. The integrated circuit may form a semiconductor chip for a memory device such as a DRAM (Dynamic Random Access Memory), a SRAM (Static Random Access Memory), a flash memory, a MRAM (Magnetic Random Access Memory), a FRAM (Ferroelectric Random Access Memory), a ReRAM (Resistive Random Access Memory), or a PRMA(Phase-change Random Access Memory). In an embodiment, the integrated circuit may be a memory circuit forming a cell array of the memory device, a logic circuit including a peripheral circuit that controls the operation of the cell array, or a combination of the memory circuit and the logic circuit.

In a planar view, the scribe lane region SR may enclose the chip region CR. In the scribe lane region SR, patterns formed by the same or similar process as the pattern formed in each chip region CR may be disposed. The patterns disposed in the scribe lane region SR may include monitoring patterns for checking the characteristics and alignment of patterns formed in the chip region CR and dummy patterns for the stability of the manufacturing process. In an embodiment, the monitoring patterns may include an overlay mark for checking alignment, and some of the dummy patterns may form a dishing inhibiting structure. The scribe lane region SR may include a separation region. After the integrated circuit is formed in the chip regions CR, a process such as dicing or sawing may be performed along the separation region. Through the process such as dicing or sawing, the wafer 101 may be divided into a plurality of semiconductor chips.

The semiconductor device according to an embodiment of the present disclosure may include various patterns formed in the plurality of chip regions CR and the scribe lane region SR of the wafer 101.

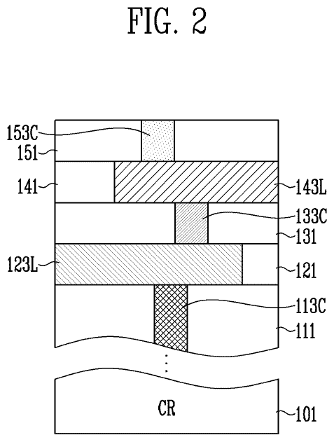

FIG. 2 is a sectional view of a semiconductor device according to an embodiment of the present disclosure taken along the chip region.

Referring to FIG. 2, the semiconductor device may include a first insulating layer 111, a second insulating layer 121, a third insulating layer 131, a fourth insulating layer 141, and a fifth insulating layer 151, which are stacked over the chip region CR of the wafer 101. The wafer 101 has a surface extending in a plane in a first direction DR1 and a second direction DR2. The first, second, third, fourth, and fifth insulating layers 111, 121, 131, 141, and 151 may be sequentially stacked in a third direction DR3 over the wafer. In an embodiment, the first, second, third, fourth, and fifth insulating layers 111, 121, 131, 141, and 151 are sequentially stacked in a vertical direction perpendicular to the surface of the wafer 101.

The semiconductor device may include a plurality of contact plugs and a plurality of conductive lines, which overlap vertically in the chip region CR of the wafer 101. In an embodiment, the plurality of contact plugs may include a first contact plug 113C disposed in the first insulating layer 111, a second contact plug 133C disposed in the third insulating layer 131, and a third contact plug 153C disposed in the fifth insulating layer 151, while the plurality of conductive lines may include a first conductive line 123L disposed in the second insulating layer 121 and a second conductive line 143L disposed in the fourth insulating layer 141. The plurality of contact plugs and the plurality of conductive lines may form part of the integrated circuit, and may be formed of various conductive materials. In an embodiment, the first contact plug 113C, the first conductive line 123L, the second contact plug 133C, the second conductive line 143L, and the third contact plug 153C may be electrically connected to each other, and form an interconnection structure.

The alignment of the plurality of contact plugs and the plurality of conductive lines may be determined by measuring the overlay mark over the scribe lane region, which is formed substantially simultaneously with the contact plugs and the conductive lines. Each of the contact plugs and the conductive lines may be formed by filling the interior of a recess region with the conductive material. The recess region may be formed by etching the insulating layer in a layer where each of the contact plugs and the plurality of conductive lines is located. In a process of filling the interior of the recess region with the conductive material, the conductive material may be left only in the recess region through a planarization process such as chemical mechanical polishing (CMP). When performing the planarization process, dishing which causes a step between the planarized conductive material and the insulating layer may occur. In order to inhibit the dishing, in an embodiment, a plurality of dummy patterns may be disposed in the region of the insulating layer of each layer overlapping the scribe lane region. The words “simultaneous” and “simultaneously” as used herein with respect to occurrences mean that the occurrences take place on overlapping intervals of time. For example, if a first occurrence takes place over a first interval of time and a second occurrence takes place simultaneously over a second interval of time, then the first and second intervals at least partially overlap each other such that there exists a time at which the first and second occurrences are both taking place.

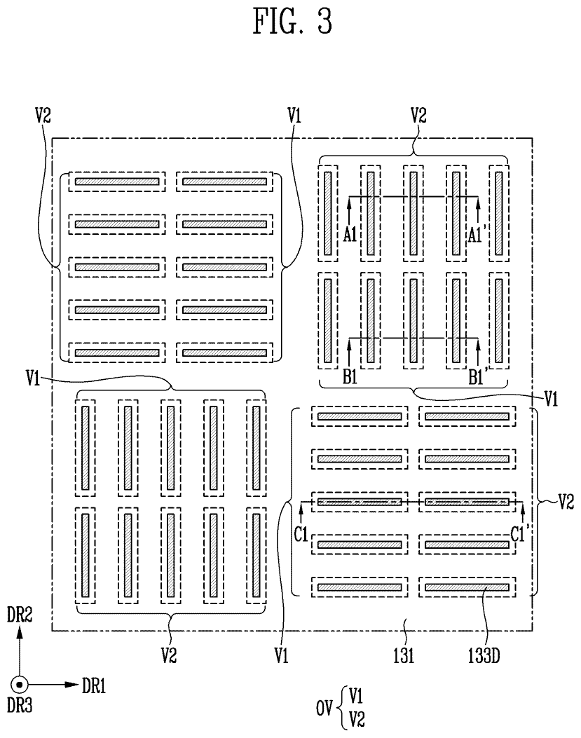

FIG. 3 is a plan view illustrating an overlay mark and a plurality of dummy patterns of the semiconductor device according to an embodiment of the present disclosure disposed in the scribe lane region.

Referring to FIG. 3, the overlay mark OV may include a plurality of first vernier patterns V1 and a plurality of second vernier patterns V2.

In a planar view, the plurality of first vernier patterns V1 may be arranged to be spaced apart from each other in the first direction DR1 or the second direction DR2, and may be formed in a bar type extending in the first direction DR1 or the second direction DR2. The bar type may have a length defined along a major axis in one of the first direction DR1 and the second direction DR2 and a width defined along a minor axis in the other direction. For example, the plurality of first vernier patterns V1 arranged to be spaced apart from each other in the first direction DR1 may be formed in a bar type with a length extending in the second direction DR2, and the plurality of first vernier patterns V1 arranged to be spaced apart from each other in the second direction DR2 may be formed in a bar type with a length extending in the first direction DR1. The first direction DR1 and the second direction DR2 are defined as the directions of two axes that intersect in a planar view.

The plurality of second vernier patterns V2 may be arranged not to overlap the plurality of first vernier patterns V1 in a vertical direction. Hereinafter, the vertical direction is referred to as the third direction DR3. Similarly to the plurality of first vernier patterns V1, in a planar view, the plurality of second vernier patterns V2 may be arranged to be spaced apart from each other in the first direction DR1 or the second direction DR2, and may be formed in a bar type extending in the first direction DR1 or the second direction DR2.

By measuring alignment between the plurality of first vernier patterns V1 and the plurality of second vernier patterns V2, the alignment between the patterns formed in the chip region may be determined. The plurality of first vernier patterns V1 and the plurality of second vernier patterns V2 may overlap a plurality of dummy patterns 133D in the third direction DR3.

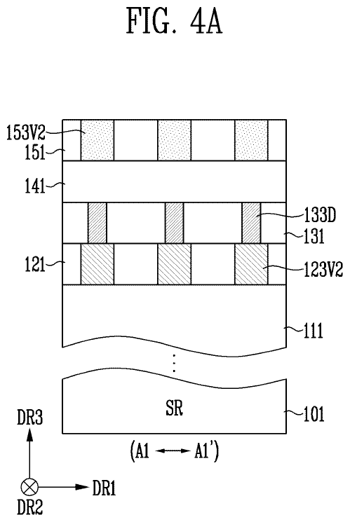

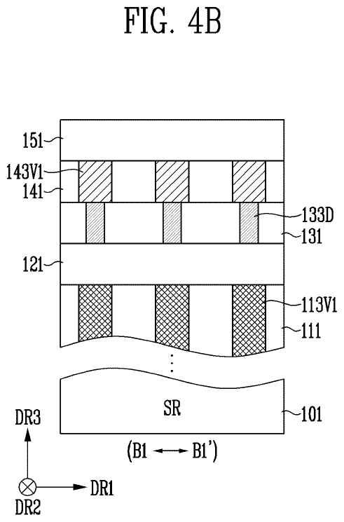

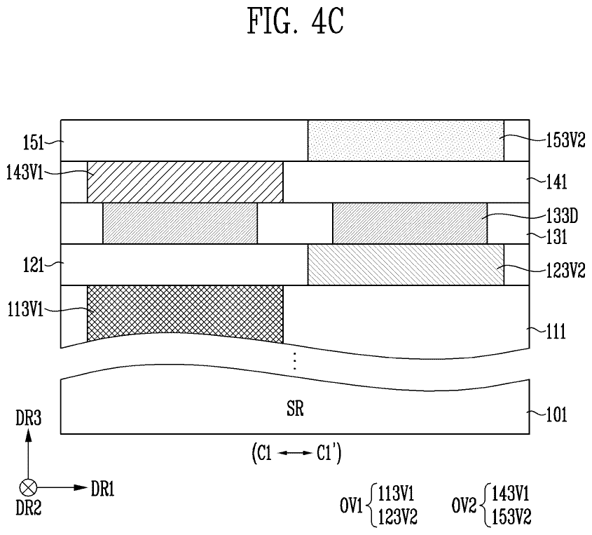

FIGS. 4A, 4B, and 4C are sectional views of the semiconductor device according to an embodiment of the present disclosure taken along line A1-A1′, line B1-B1′, and line C1-C1′ shown in FIG. 3.

Referring to FIGS. 3, 4A, 4B, and 4C, the overlay mark OV may be divided into a first overlay mark OV1 disposed under the plurality of dummy patterns 133D and a second overlay mark OV2 disposed above the plurality of dummy patterns 133D. The plurality of first vernier patterns V1 may be divided into a plurality of first lower vernier patterns 113V1 of the first overlay mark OV1 and a plurality of first upper vernier patterns 143V1 of the second overlay mark OV2. The plurality of second vernier patterns V2 may be divided into a plurality of second lower vernier patterns 123V2 of the first overlay mark OV1 and a plurality of second upper vernier patterns 153V2 of the second overlay mark OV2.

The plurality of dummy patterns 133D are arranged at a level between the first overlay mark OV1 and the second overlay mark OV2. At this time, the plurality of dummy patterns 133D may be formed with a smaller area compared to the plurality of first lower vernier patterns 113V1 and the plurality of second lower vernier patterns 123V2 of the first overlay mark OV1, and may overlap them in the third direction DR3. In an embodiment, each of the plurality of dummy patterns 133D is formed with an area smaller than that of each of the plurality of lower vernier patterns (i.e., 113V1 and 123V2) overlapping in the third direction DR3. For example, each of the plurality of dummy patterns 133D has a first area and each of the plurality of first lower vernier patterns 113V1 has a second area greater than the first area. For example, each of the plurality of dummy patterns 133D has a first area and each of the plurality of second lower vernier patterns 123V2 has a third area greater than the first area. In an embodiment, the area (i.e. the first area) of a dummy pattern 133D may be an area measured along the first and second directions DR1 and DR2. In an embodiment, the area (i.e., the second area) of a first lower vernier pattern 113V1 may be an area measured along the first and second directions DR1 and DR2. In an embodiment, the area (i.e., third area) of a second lower vernier pattern 123V2 may be an area measured along the first and second directions DR1 and DR2. In an embodiment, the second area of a first lower vernier pattern 113V1 may have the same area as the third area of a second lower vernier pattern 123V2. The plurality of first upper vernier patterns 143V1 and the plurality of second upper vernier patterns 153V2 of the second overlay mark OV2 may be formed with a larger area compared to the plurality of dummy patterns 133D, and may overlap them in the third direction DR3. In an embodiment, each of the plurality of dummy patterns 133D is formed with an area smaller than that of each of the plurality of upper vernier patterns (i.e., 143V1 and 153V2) overlapping in the third direction DR3. For example, each of the plurality of dummy patterns 133D has a first area and each of the plurality of first upper vernier patterns 143V1 has a fourth area greater than the first area. For example, each of the plurality of dummy patterns 133D has a first area and each of the plurality of second upper vernier patterns 153V2 has a fifth area greater than the first area. In an embodiment, the area (i.e. the first area) of a dummy pattern 133D may be an area measured along the first and second directions DR1 and DR2. In an embodiment, the area (i.e., the fourth area) of a first upper vernier pattern 143V1 may be an area measured along the first and second directions DR1 and DR2. In an embodiment, the area (i.e., fifth area) of a second upper vernier pattern 153V2 may be an area measured along the first and second directions DR1 and DR2. In an embodiment, the fourth area of a first upper vernier pattern 143V1 may have the same area as the fifth area of a second upper vernier pattern 153V2.

The first insulating layer 111, the second insulating layer 121, the third insulating layer 131, the fourth insulating layer 141, and the fifth insulating layer 151 may extend to overlap the scribe lane region SR of the wafer 101. The plurality of first lower vernier patterns 113V1 may overlap the scribe lane region SR of the wafer 101 in the third direction DR3, and may be disposed in the first insulating layer 111. The plurality of second lower vernier patterns 123V2 may overlap the scribe lane region SR of the wafer 101 in the third direction DR3, and may be disposed in the second insulating layer 121. The plurality of dummy patterns 133D may overlap the scribe lane region SR of the wafer 101 in the third direction DR3, and may be disposed in the third insulating layer 131. The plurality of first upper vernier patterns 143V1 may overlap the scribe lane region SR of the wafer 101 in the third direction DR3, and may be disposed in the fourth insulating layer 141. The plurality of second upper vernier patterns 153V2 may overlap the scribe lane region SR of the wafer 101 in the third direction DR3, and may be disposed in the fifth insulating layer 151.

Referring to FIGS. 2, 4A, 4B, and 4C, the plurality of first lower vernier patterns 113V1 may be formed using a process of forming the first contact plug 113C, and may include the same conductive material as the first contact plug 113C. The plurality of second lower vernier patterns 123V2 may be formed using a process of forming the first conductive line 123L, and may include the same conductive material as the first conductive line 123L. The plurality of second lower vernier patterns 123V2 might not overlap the plurality of first lower vernier patterns 113V1 but may overlap the first insulating layer 111 in the third direction DR3. Thus, in an embodiment, the positions of the plurality of first lower vernier patterns 113V1 and the plurality of second lower vernier patterns 123V2 may be optically detected. In an embodiment, based on the detection signal, the alignment between the plurality of first lower vernier patterns 113V1 and the plurality of second lower vernier patterns 123V2 may be measured, and the alignment between the first contact plug 113C and the first conductive line 123L may be determined.

The plurality of dummy patterns 133D may be formed using a process of forming the second contact plug 133C, and may include the same conductive material as the second contact plug 133C. In an embodiment, the plurality of dummy patterns 133D may be used as the dishing inhibiting structure while the planarization process is performed so that the third insulating layer 131 is exposed.

The plurality of first upper vernier patterns 143V1 may be formed using a process of forming the second conductive line 143L, and may include the same conductive material as the second conductive line 143L. The plurality of second upper vernier patterns 153V2 may be formed using a process of forming the third contact plug 153C, and may include the same conductive material as the third contact plug 153C. The plurality of second upper vernier patterns 153V2 might not overlap the plurality of first upper vernier patterns 143V1 but may overlap the fourth insulating layer 141 in the third direction DR3. Thus, in an embodiment, the positions of the plurality of first upper vernier patterns 143V1 and the plurality of second upper vernier patterns 153V2 may be optically detected. In an embodiment, based on the detection signal, the alignment between the plurality of first upper vernier patterns 143V1 and the plurality of second upper vernier patterns 153V2 may be measured, and the alignment between the third contact plug 153C and the second conductive line 143L may be determined.

The plurality of first upper vernier patterns 143V1 and the plurality of second upper vernier patterns 153V2 may overlap the plurality of dummy patterns 133D in the vertical direction, and each of the plurality of first upper vernier patterns 143V1 and the plurality of second upper vernier patterns 153V2 may be formed with a larger area than each of the plurality of dummy patterns 133D. Thus, in an embodiment, because the interference of a detection signal caused by the plurality of dummy patterns 133D may be reduced in the process of measuring the alignment between the plurality of first upper vernier patterns 143V1 and the plurality of second upper vernier patterns 153V2, the stability of the manufacturing process of the semiconductor device can be ensured.

In an embodiment, to further reduce the interference of the detection signal, the plurality of first upper vernier patterns 143V1 may overlap the plurality of first lower vernier patterns 113V1 in the third direction DR3, and the plurality of second upper vernier patterns 153V2 may overlap the plurality of second lower vernier patterns 123V2 in the third direction DR3. Each of the plurality of first upper vernier patterns 143V1 and the plurality of second upper vernier patterns 153V2 may be formed with substantially the same area as each of the plurality of first lower vernier patterns 113V1 and the plurality of second lower vernier patterns 123V2, or be formed with a larger area than each of the plurality of first lower vernier patterns 113V1 and the plurality of second lower vernier patterns 123V2.

In an embodiment, the plurality of dummy patterns 133D may overlap the first overlay mark OV1 and may be used as the dishing inhibiting structure, thereby reducing the area of the scribe lane region SR allocated to the dishing inhibiting structure. In an embodiment, the second overlay mark OV2 may overlap the first overlay mark OV1 and the plurality of dummy patterns 133D, thereby reducing the area of the scribe lane region SR allocated to the vernier patterns.

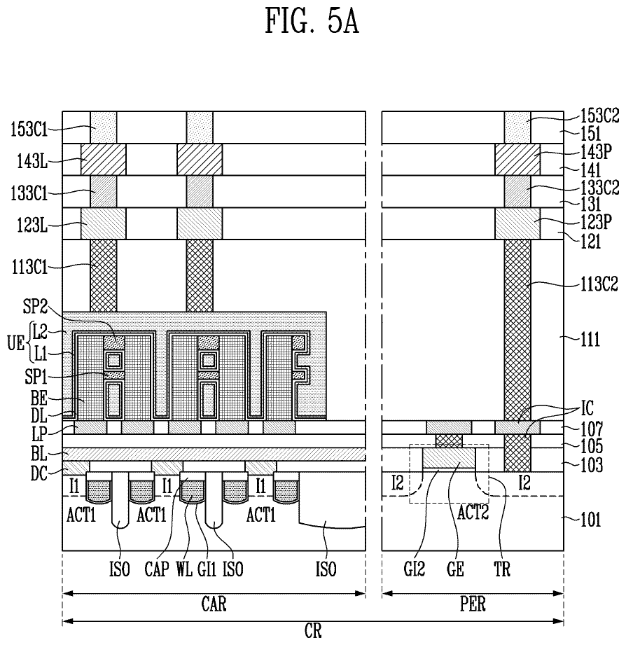

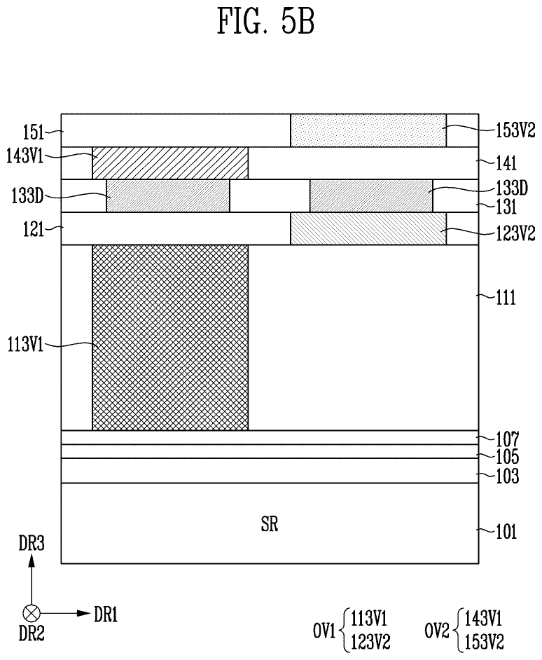

FIGS. 5A and 5B are sectional views illustrating the chip region and the scribe lane region of the semiconductor device according to an embodiment of the present disclosure.

Referring to FIG. 5A, the chip region CR of the wafer 101 may include a cell array region CAR and a peripheral circuit region PER. In an embodiment, a DRAM element may be formed on the cell array region CAR and the peripheral circuit region PER of the wafer 101. Hereinafter, one example of the DRAM element formed on the chip region CR of the wafer 101 will be described.

The wafer 101 may be partitioned into a plurality of active regions ACT1 and ACT2 by isolation layers ISO. The plurality of active regions ACT1 and ACT2 may include a first active region ACT1 disposed in the cell array region CAR and a second active region ACT2 disposed in the peripheral circuit region PER.

A memory cell transistor coupled to a word line WL and a bit line BL and a capacitor coupled to the memory cell transistor may be formed in the cell array region CAR of the wafer 101.

The word line WL may be embedded in the wafer 101. A cell gate insulating layer GI1 is interposed between the word line WL and the wafer 101. A capping pattern CAP may be disposed over the word line WL. The word line WL may serve as a gate of the memory cell transistor. The capping pattern CAP may include an insulating material such as silicon nitride. A first impurity implantation region I1 may be disposed in the first active region ACT1 on a side of the word line WL. Although not shown in the drawing, a separate impurity implantation region may be disposed in part of the first active region ACT1 facing the first impurity implantation region I1 with the word line WL interposed therebetween. The above-described first impurity implantation region I1 and the separate impurity implantation region may serve as a source region and a drain region of the memory cell transistor.

The bit line BL may be electrically connected to the first impurity implantation region I1 of the first active region ACT1 through a bit line contact plug DC. The bit line BL may be spaced apart from the first active region ACT1 with a first interlayer insulating layer of the first lower insulating structure 103 interposed therebetween. The bit line contact plug DC may penetrate the first interlayer insulating layer of the first lower insulating structure 103 to directly contact the first impurity implantation region I1. The bit line BL may be embedded in a second interlayer insulating layer of the first lower insulating structure 103. The second interlayer insulating layer may be disposed over the first interlayer insulating layer.

The bit line BL may be covered with a second lower insulating structure 105. The bit line BL may be spaced apart from a landing pad LP by the second lower insulating structure 105. The landing pad LP may be embedded in a third lower insulating structure 107 over the second lower insulating structure 105. Although not shown in the drawing, the landing pad LP may be coupled to the separate impurity implantation region of the first active region ACT1 via a lower contact plug. Thus, the source region of the memory cell transistor may be electrically connected to the bit line BL via the bit line contact plug DC, and the drain region of the memory cell transistor may be electrically connected to a bottom electrode BE of the capacitor via the landing pad LP and the lower contact plug.

The word line WL, the bit line BL, the bit line contact plug DC, and the landing pad LP may be formed of various conductive materials.

The capacitor coupled to the landing pad LP may include the bottom electrode BE, a dielectric layer DL, and an upper electrode UE.

The bottom electrode BE may be formed of various conductive materials. The bottom electrode BE may be coupled to the landing pad LP in various shapes. In an embodiment, the bottom electrode BE may be formed in a pillar shape. Although not shown in the drawing, in an embodiment, the bottom electrode BE may be formed in a cylindrical shape. A first support pattern SP1 and a second support pattern SP2 may be disposed on a side of the bottom electrode BE. The first support pattern SP1 and the second support pattern SP2 may be disposed at different distances from the wafer 101 and spaced apart from each other. The bottom electrode BE may be spaced apart from another bottom electrode BE by the first support pattern SP1 and the second support pattern SP2. The first support pattern SP1 and the second support pattern SP2 may include an insulating material such as silicon oxide.

The dielectric layer DL may extend along a surface of each of the first support pattern SP1 and the second support pattern SP2 and a surface of the bottom electrode BE which does not contact the first support pattern SP1 and the second support pattern SP2. The dielectric layer DL may contain an oxide, a nitride, an oxynitride, or a silicon oxynitride. The dielectric layer DL may contain a metal such as hafnium, aluminum, zirconium, or lanthanum.

The upper electrode UE may include a first conductive layer L1 and a second conductive layer L2. The first conductive layer L1 may be a metal nitride layer such as a titanium nitride layer. The second conductive layer L2 may include a doped semiconductor layer such as a doped silicon layer or a metal layer such as tungsten.

A transistor TR forming the peripheral circuit may be formed in the peripheral circuit region PER of the wafer 101. The transistor TR includes a gate insulating layer GI2, a gate electrode GE, and second impurity implantation regions I2. The gate insulating layer GI2 and the gate electrode GE are stacked over the second active region ACT2. The gate insulating layer GI2 and the gate electrode GE may be embedded in the first lower insulating structure 103. The second impurity implantation regions I2 may be disposed in the second active region ACT2 on one side and the other side of the gate electrode GE, and may serve as the source region and the drain region.

The second lower insulating structure 105 and the third lower insulating structure 107 may extend onto the peripheral circuit region PER of the wafer 101 to cover the transistor TR and the first lower insulating structure 103. The transistor TR may be coupled to conductive patterns of a lower interconnection structure IC that penetrate one or more of the first lower insulating structure 103, the second lower insulating structure 105, and the third lower insulating structure 107.

The upper electrode UE and the lower interconnection structure IC may be covered with the first insulating layer 111. The second insulating layer 121, the third insulating layer 131, the fourth insulating layer 141, and the fifth insulating layer 151 may be stacked over the first insulating layer 111.

First contact plugs 113C1 and 113C2 may be disposed in the first insulating layer 111. The first contact plugs 113C1 and 113C2 may include a first cell contact plug 113C1 electrically connected to the upper electrode UE, and a first peripheral contact plug 113C2 electrically connected to the lower interconnection structure IC.

The first conductive line 123L and a first conductive pad 123P may be disposed in the second insulating layer 121. The first conductive line 123L may be coupled to the first cell contact plug 113C1, and the first conductive pad 123P may be coupled to the first peripheral contact plug 113C2.

Second contact plugs 133C1 and 133C2 may be disposed in the third insulating layer 131. The second contact plugs 133C1 and 133C2 may include a second cell contact plug 133C1 electrically connected to the first conductive line 123L, and a second peripheral contact plug 133C2 electrically connected to the first conductive pad 123P.

The second conductive line 143L and a second conductive pad 143P may be disposed in the fourth insulating layer 141. The second conductive line 143L may be coupled to the second cell contact plug 133C1, and the second conductive pad 143P may be coupled to the second peripheral contact plug 133C2.

Third contact plugs 153C1 and 153C2 may be disposed in the fifth insulating layer 151. The third contact plugs 153C1 and 153C2 may include a third cell contact plug 153C1 electrically connected to the second conductive line 143L, and a third peripheral contact plug 153C2 electrically connected to the second conductive pad 143P.

The alignment of the first contact plugs 113C1 and 113C2, first conductive line 123L, first conductive pad 123P, second contact plugs 133C1 and 133C2, second conductive line 143L, second conductive pad 143P, and third contact plugs 153C1 and 153C2 described above may be determined by measuring the overlay mark OV1 or OV2 over the scribe lane region SR of the wafer 101 shown in FIG. 5B.

Referring to FIG. 5B, the layout of each of the first overlay mark OV1 and the second overlay mark OV2 may be substantially same as the layout of the overlay mark OV shown in FIG. 3. FIG. 5B shows the sectional view of the first overlay mark OV1 and the second overlay mark OV2 taken along line C1-C1′ of FIG. 3.

Each of the first overlay mark OV1 and the second overlay mark OV2 may be disposed with the plurality of dummy patterns 133D interposed therebetween. The layout of the plurality of dummy patterns 133D may be substantially same as the layout of the plurality of dummy patterns shown in FIG. 3.

The first lower insulating structure 103, the second lower insulating structure 105, the third lower insulating structure 107, the first insulating layer 111, the second insulating layer 121, the third insulating layer 131, the fourth insulating layer 141, and the fifth insulating layer 151 shown in FIG. 5A may extend to overlap the scribe lane region SR of the wafer 101.

The plurality of first lower vernier patterns 113V1 of the first overlay mark OV1 may overlap the scribe lane region SR of the wafer 101 in the third direction DR3, and may be disposed in the first insulating layer 111. The plurality of first lower vernier patterns 113V1 may be disposed over the third lower insulating structure 107. The plurality of second lower vernier patterns 123V2 of the first overlay mark OV1 may overlap the scribe lane region SR in the third direction DR3, and may be disposed in the second insulating layer 121.

The plurality of dummy patterns 133D may overlap the scribe lane region SR of the wafer 101 in the third direction DR3, and may be disposed in the third insulating layer 131.

The plurality of first upper vernier patterns 143V1 of the second overlay mark OV2 may overlap the scribe lane region SR of the wafer 101 in the third direction DR3, and may be disposed in the fourth insulating layer 141. The plurality of second upper vernier patterns 153V2 of the second overlay mark OV2 may overlap the scribe lane region SR of the wafer 101 in the third direction DR3, and may be disposed in the fifth insulating layer 151.

Referring to FIGS. 5A and 5B, the plurality of first lower vernier patterns 113V1 may be formed using the process of forming the first contact plugs 113C1 and 113C2, and may include the same conductive material as the first contact plugs 113C1 and 113C2. The plurality of second lower vernier patterns 123V2 may be formed using the process of forming the first conductive line 123L and the first conductive pad 123P, and may include the same conductive material as the first conductive line 123L and the first conductive pad 123P. The plurality of second lower vernier patterns 123V2 might not overlap the plurality of first lower vernier patterns 113V1 but may overlap the first insulating layer 111 in the third direction DR3.

The plurality of dummy patterns 133D may be formed using the process of forming the second contact plugs 133C1 and 133C2, and may include the same conductive material as the second contact plugs 133C1 and 133C. In an embodiment, the plurality of dummy patterns 133D may be used as the dishing inhibiting structure while the planarization process is performed so that the third insulating layer 131 is exposed.

The plurality of first upper vernier patterns 143V1 may be formed using a process of forming the second conductive line 143L and the second conductive pad 143P, and may include the same conductive material as the second conductive line 143L and the second conductive pad 143P. The plurality of second upper vernier patterns 153V2 may be formed using a process of forming the third contact plugs 153C1 and 153C2, and may include the same conductive material as the third contact plug 153C1 and 153C2. The plurality of second upper vernier patterns 153V2 might not overlap the plurality of first upper vernier patterns 143V1 but may overlap the fourth insulating layer 141 in the third direction DR3.

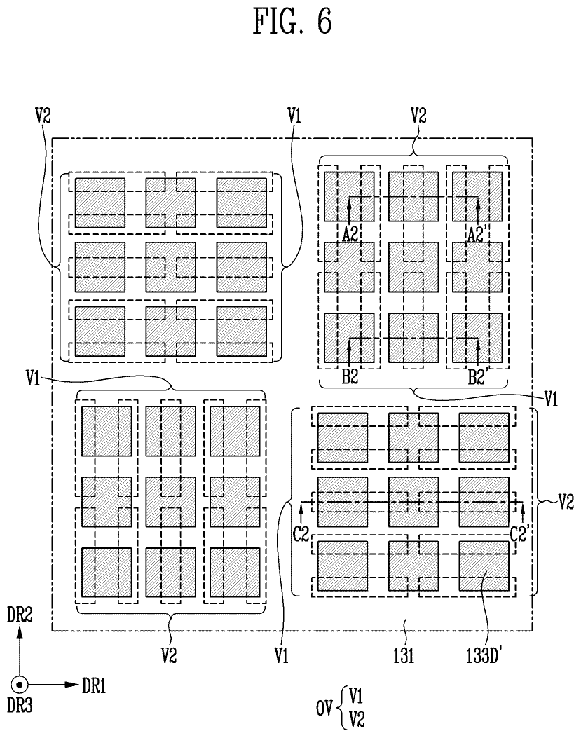

FIG. 6 is a plan view illustrating an overlay mark and a plurality of dummy patterns of the semiconductor device according to an embodiment of the present disclosure disposed in the scribe lane region.

Referring to FIG. 6, as described with reference to FIG. 3, the overlay mark OV may include a plurality of first vernier patterns V1 and a plurality of second vernier patterns V2.

In a planar view, a plurality of dummy patterns 133D′ may be arranged to be spaced apart from each other in the first direction DR1 and the second direction DR2. Part of each of the dummy patterns 133D′ may overlap the overlay mark OV in the third direction DR3, another part might not overlap the overlay mark OV.

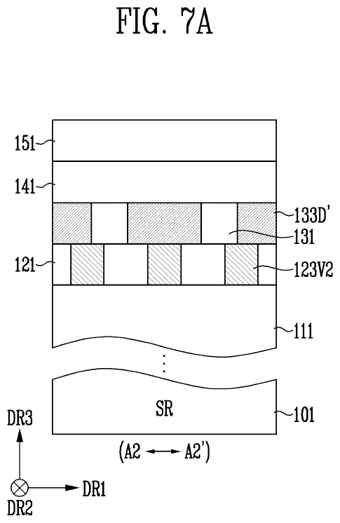

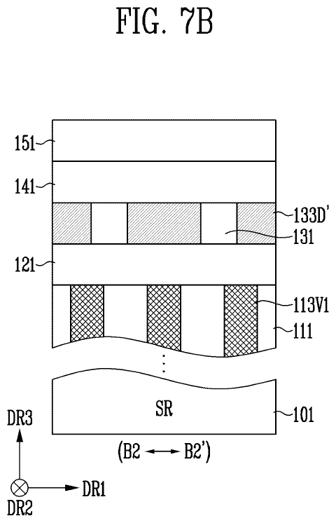

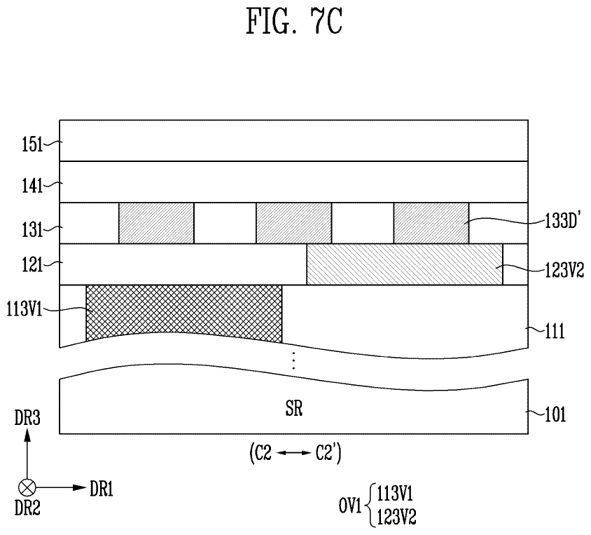

FIGS. 7A, 7B, and 7C are sectional views of the semiconductor device according to an embodiment of the present disclosure taken along line A2-A2′, line B2-B2′, and line C2-C2′ shown in FIG. 6.

Referring to FIGS. 6, 7A, 7B, and 7C, the overlay mark OV may be the first overlay mark OV1 disposed under the plurality of dummy patterns 133D′. The plurality of first vernier patterns V1 may be the plurality of first lower vernier patterns 113V1 of the first overlay mark OV1, and the plurality of second vernier patterns V2 may be the plurality of second lower vernier patterns 123V2 of the first overlay mark OV1.

The first insulating layer 111, the second insulating layer 121, the third insulating layer 131, the fourth insulating layer 141, and the fifth insulating layer 151 may extend to overlap the scribe lane region SR of the wafer 101.

As described with reference to FIGS. 4A, 4B, and 4C, the plurality of first lower vernier patterns 113V1 may be disposed in the first insulating layer 111, and may include the same conductive material as the first contact plug 113C shown in FIG. 2. As described with reference to FIGS. 4A, 4B, and 4C, the plurality of second lower vernier patterns 123V2 may be disposed in the second insulating layer 121, and may include the same conductive material as the first conductive line 123L shown in FIG. 2. As described with reference to FIGS. 4A, 4B, and 4C, the alignment between the plurality of first lower vernier patterns 113V1 and the plurality of second lower vernier patterns 123V2 may be measured based on the detection signals for the plurality of first lower vernier patterns 113V1 and the plurality of second lower vernier patterns 123V2, and the alignment between the first contact plug 113C and the first conductive line 123L shown in FIG. 2 may be determined.

The plurality of dummy patterns 133D′ may overlap the scribe lane region SR in the third direction DR3, and may be disposed in the third insulating layer 131. The plurality of dummy patterns 133D′ may include the same conductive material as the second contact plug 133C shown in FIG. 2. In a planar view, each dummy pattern 133D′ may be formed with a wider width compared to each first lower vernier pattern 113V1 or each second lower vernier pattern 123V2. In this case, a separate overlay mark might not be superimposed above the dummy pattern 133D′, and the overlay mark corresponding to the second conductive line 143L and the third contact plug 153C shown in FIG. 2 may be disposed in a separate region (not shown) that does not overlap a region for the first overlay mark OV1 and the dummy pattern 133D′. Thus, in an embodiment, because the detection signal for the overlay mark corresponding to the second conductive line 143L and the third contact plug 153C may be prevented or mitigated from being distorted due to the dummy pattern 133D′, the stability of the manufacturing process of the semiconductor device may be ensured.

In an embodiment, the plurality of dummy patterns 133D′ may overlap the first overlay mark OV1 and used as the dishing inhibiting structure, thereby reducing the area of the scribe lane region SR allocated to the dishing inhibiting structure. In an embodiment, because no other overlay marks are not arranged above the dummy pattern 133D′, the plurality of dummy patterns 133D′ may be covered with the fourth insulating layer 141 and the fifth insulating layer 151. For example, top surfaces of the plurality of dummy patterns 133D′ are not blocked by the other overlay marks and overlap each of the fourth insulating layer 141 and the fifth insulating layer 151 in the third direction DR3. In an embodiment, the top surfaces of the plurality of dummy patterns 133D′ may be completely covered with each of the fourth insulating layer 141 and the fifth insulating layer 151.

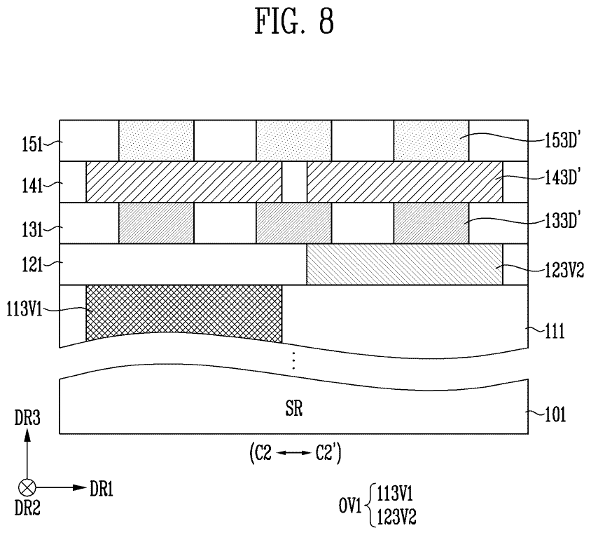

FIG. 8 is a sectional view illustrating an overlay mark and multilayer dummy patterns of the semiconductor device according to an embodiment of the present disclosure disposed in the scribe lane region. FIG. 8 is a sectional view of the semiconductor device taken along line C2-C2′ shown in FIG. 6.

Referring to FIGS. 6 and 8, as described with reference to FIGS. 7A, 7B, and 7C, the first insulating layer 111, the second insulating layer 121, the third insulating layer 131, the fourth insulating layer 141, and the fifth insulating layer 151 may overlap the scribe lane region SR of the wafer 101, and the first lower vernier pattern 113V1 of the first overlay mark OV1 may be disposed in the first insulating layer 111, and the second lower vernier pattern 123V2 of the first overlay mark OV1 may be disposed in the second insulating layer 121, and the dummy pattern 133D′ may be disposed in the third insulating layer 131.

The semiconductor device may include a plurality of first upper dummy patterns 143D′ or a plurality of second upper dummy patterns 153D′, or may include both the plurality of first upper dummy patterns 143D′ and the plurality of second upper dummy patterns 153D′. In an embodiment, the plurality of first upper dummy patterns 143D′ may be used as a dishing inhibiting structure, and may be disposed in the fourth insulating layer 141. The plurality of second upper dummy patterns 153D′ may be used as another dishing inhibiting structure, and may be disposed in the fifth insulating layer 151.

In an embodiment, by arranging the dummy patterns in multiple layers as described above, the planar area of the scribe lane region allocated to the dishing inhibiting structure during the manufacture of the semiconductor device can be reduced.

Hereinafter, a manufacturing process performed in the scribe lane region of the semiconductor device according to an embodiment of the present disclosure will be described.

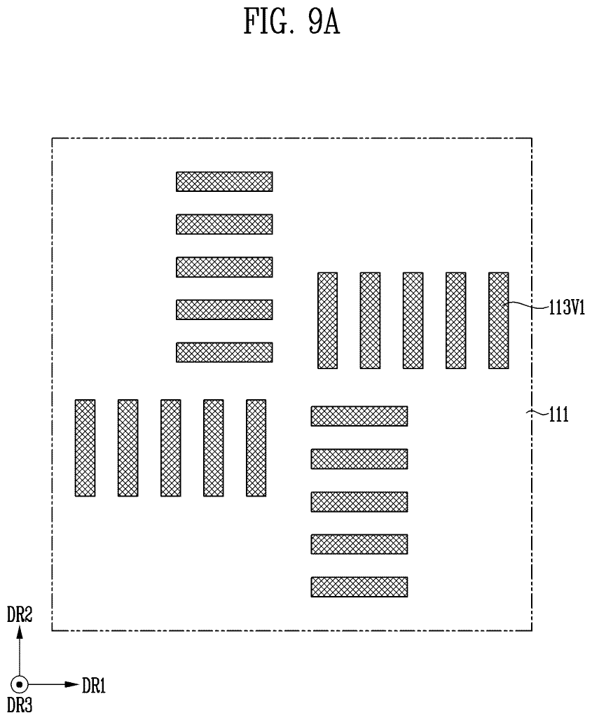

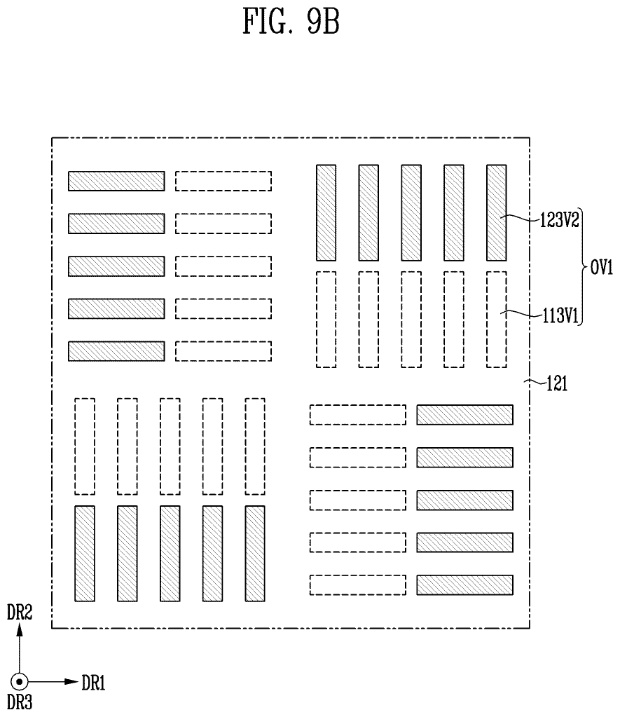

FIGS. 9A and 9B are plan views illustrating a first overlay mark according to an embodiment of the present disclosure.

Referring to FIG. 9A, a first insulating layer 111 may be formed over a substructure including the wafer. Subsequently, part of the first insulating layer 111 may be etched to form a plurality of first recess regions. Thereafter, the plurality of first recess regions may be filled with a conductive material, and the conductive material may be separated into a plurality of first lower vernier patterns 113V1 through the planarization process.

Referring to FIG. 9B, a second insulating layer 121 may be formed to cover the plurality of first lower vernier patterns 113V1. Thereafter, part of the second insulating layer 121 may be etched to form a plurality of second recess regions. Subsequently, the plurality of second recess regions may be filled with a conductive material, and the conductive material may be separated into a plurality of second lower vernier patterns 123V2 through the planarization process.

Thereafter, the alignment between the plurality of first lower vernier patterns 113V1 and the plurality of second lower vernier patterns 123V2 may be measured using a first overlay mark OV1 including the first lower vernier patterns 113V1 and the second lower vernier patterns 123V2.

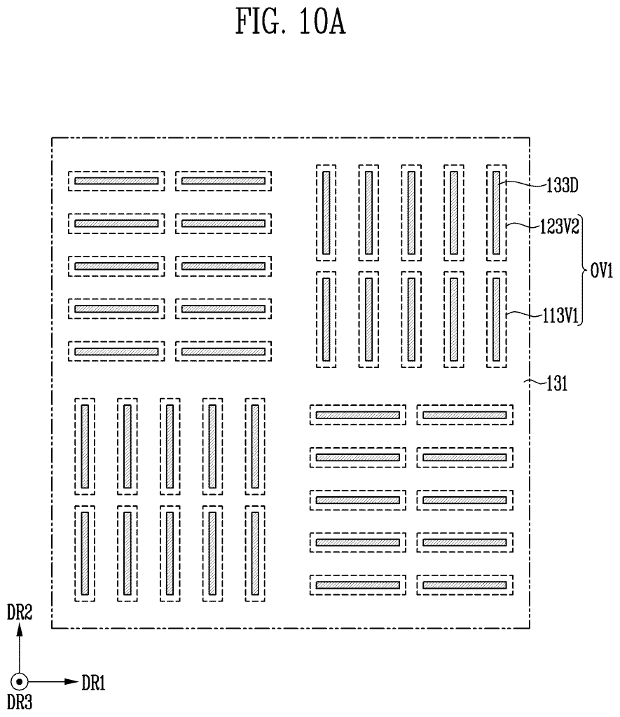

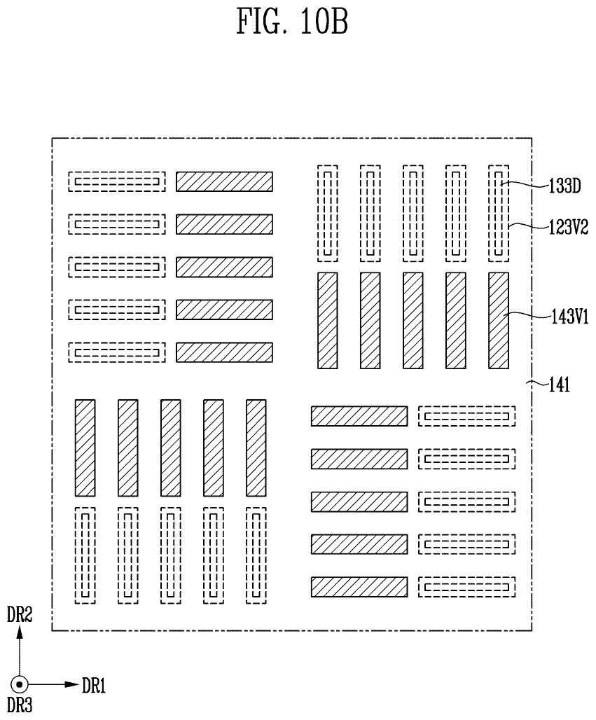

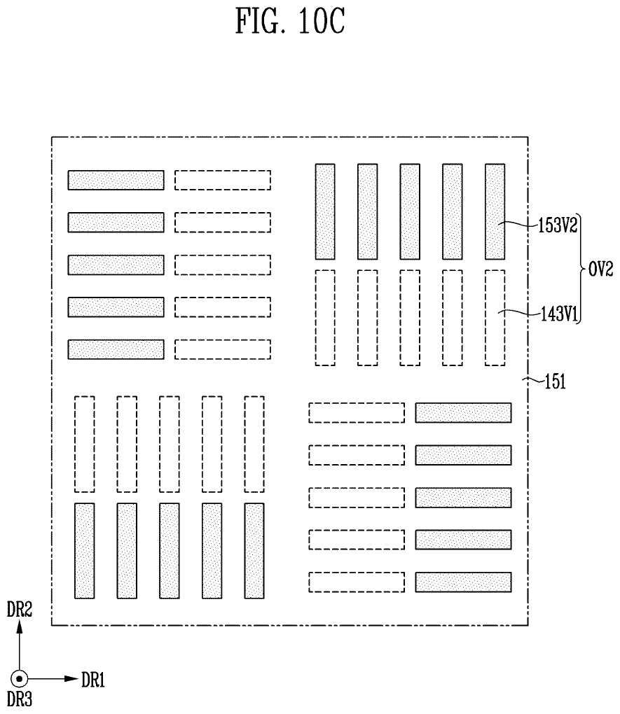

FIGS. 10A, 10B, and 10C are plan views illustrating a plurality of dummy patterns and a second overlay mark according to an embodiment of the present disclosure.

Referring to FIG. 10A, a third insulating layer 131 may be formed to cover the first overlay mark OV1 described with reference to FIG. 9B. Subsequently, part of the third insulating layer 131 may be etched to form a plurality of third recess regions. The plurality of third recess regions may overlap the plurality of first lower vernier patterns 113V1 and the plurality of second lower vernier patterns 123V2, respectively, and each third recess region may be formed with a smaller area compared to each first lower vernier pattern 113V1 or each second lower vernier pattern 123V2. Thereafter, the plurality of third recess regions may be filled with a conductive material, and the conductive material may be separated into a plurality of dummy patterns 133D through the planarization process.

In an embodiment, the plurality of dummy patterns 133D may be used as a dishing inhibiting pattern. In an embodiment, because the plurality of dummy patterns 133D are formed after a measurement process using the first overlay mark OV1, the dummy patterns 133D do not affect the measurement process using the first overlay mark OV1.

Referring to FIG. 10B, a fourth insulating layer 141 may be formed to cover the plurality of dummy patterns 133D. Subsequently, part of the fourth insulating layer 141 may be etched to form a plurality of fourth recess regions. The plurality of fourth recess regions may overlap some of the plurality of dummy patterns 133D and the plurality of first lower vernier patterns 113V1 shown in FIG. 10A. Each fourth recess region may be formed with a larger area compared to each dummy pattern 133D. Each fourth recess region may be formed with substantially the same area as the first lower vernier pattern 113V1 shown in FIG. 10A, or may be formed with a larger area compared to the first lower vernier pattern 113V1 shown in FIG. 10A. Subsequently, the plurality of fourth recess regions may be filled with a conductive material, and the conductive material may be separated into a plurality of first upper vernier patterns 143V1 through the planarization process.

Referring to FIG. 10C, a fifth insulating layer 151 may be formed to cover the plurality of first upper vernier patterns 143V1. Thereafter, part of the fifth insulating layer 151 may be etched to form a plurality of fifth recess regions. Subsequently, the plurality of fifth recess regions may be filled with a conductive material, and the conductive material may be separated into a plurality of second upper vernier patterns 153V2 through the planarization process.

Thereafter, the alignment between the plurality of first upper vernier patterns 143V1 and the plurality of second upper vernier patterns 153V2 may be measured using a second overlay mark OV2 including the first upper vernier patterns 143V1 and the second upper vernier patterns 153V2.

The semiconductor device illustrated in FIGS. 3, 4A, 4B, and 4C or the semiconductor device illustrated in FIGS. 5A and 5B may be provided using the processes described with reference to FIGS. 10A to 10C.

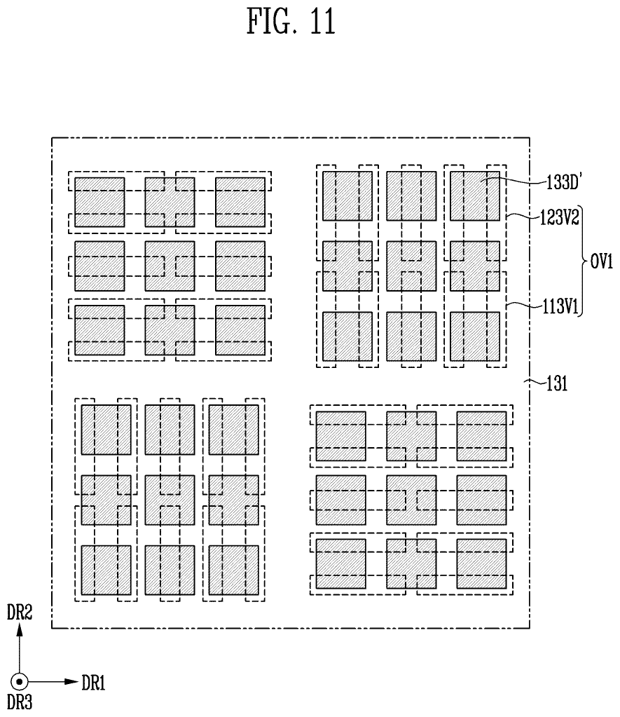

FIG. 11 is a plan view illustrating a first overlay mark and a plurality of dummy patterns according to an embodiment of the present disclosure.

Referring to FIG. 11, a third insulating layer 131 may be formed to cover the first overlay mark OV1 described with reference to FIG. 9B. Thereafter, part of the third insulating layer 131 may be etched to form a plurality of third recess regions. The plurality of third recess regions may overlap the plurality of first lower vernier patterns 113V1 and the plurality of second lower vernier patterns 123V2, respectively. Each third recess region may have a width wider than that of each first lower vernier pattern 113V1 or each second lower vernier pattern 123V2. In an embodiment, each of the first lower vernier pattern 113V1 and the second lower vernier pattern 123V2 may be formed as a rectangle, and the third recess region may be formed as a square having a wider width than a shorter side of the rectangle. However, the embodiment of the present disclosure is not limited thereto. Subsequently, the plurality of third recess regions may be filled with a conductive material, and the conductive material may be separated into a plurality of dummy patterns 133D′ through the planarization process.

In an embodiment, the plurality of dummy patterns 133D′ may be used as a dishing inhibiting pattern. In an embodiment, because the plurality of dummy patterns 133D′ are formed after a measurement process using the first overlay mark OV1, the dummy patterns 133D′ do not affect the measurement process using the first overlay mark OV1.

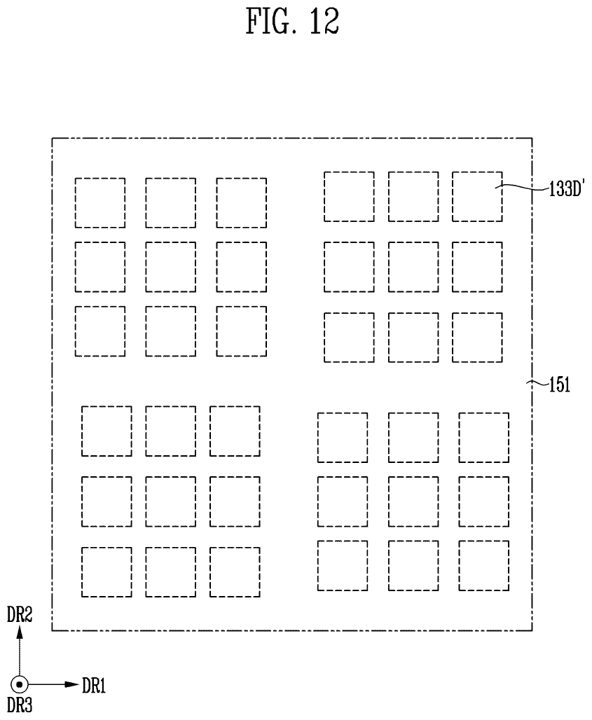

FIG. 12 is a plan view illustrating an insulating layer over a plurality of dummy patterns according to an embodiment of the present disclosure.

Referring to FIG. 12, insulating layers may be stacked to cover the plurality of dummy patterns 133D′ shown in FIG. 11. The insulating layers may include a fourth insulating layer 141 and a fifth insulating layer 151 shown in FIGS. 7A to 7C. As described with reference to FIGS. 7A to 7C, each of the fourth insulating layer 141 and the fifth insulating layer 151 may be formed to cover the plurality of dummy patterns 133D′. In an embodiment, top surfaces of the plurality of dummy patterns 133D′ may be completely covered with each of the fourth insulating layer 141 and the fifth insulating layer 151.

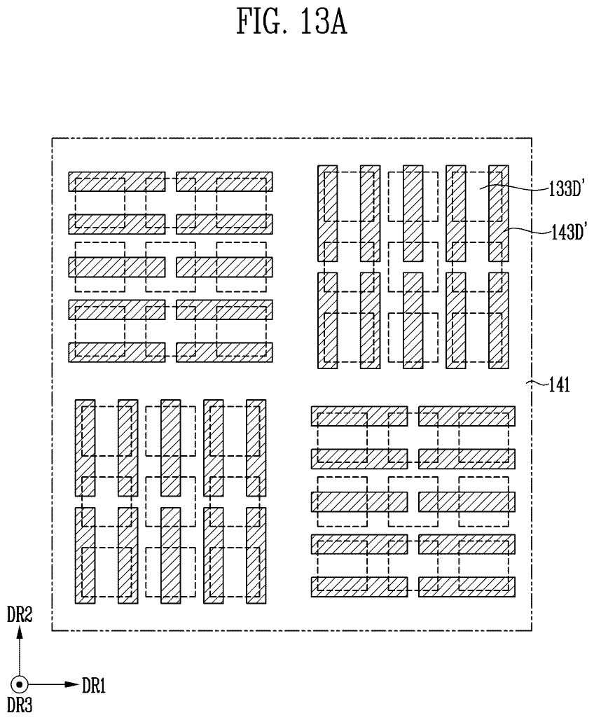

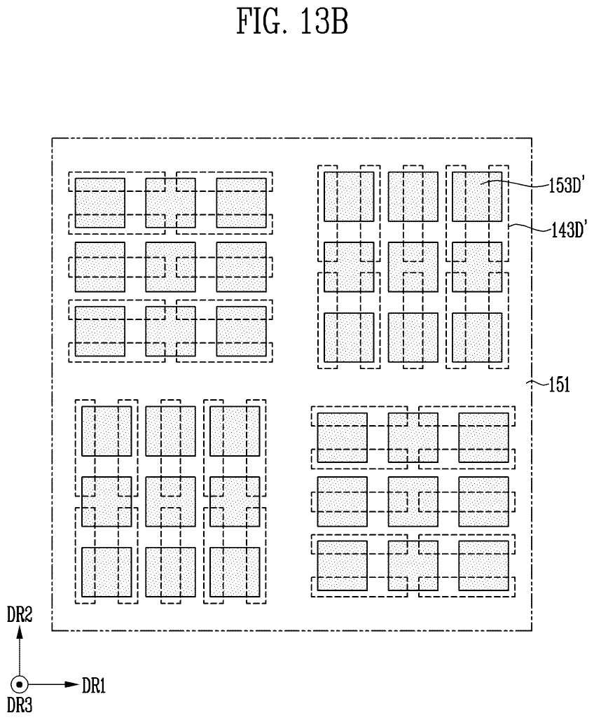

FIGS. 13A and 13B are plan views illustrating multilayer dummy patterns according to an embodiment of the present disclosure.

Referring to FIG. 13A, a fourth insulating layer 141 may be formed to cover the plurality of dummy patterns 133D′ shown in FIG. 11. Thereafter, part of the fourth insulating layer 141 may be etched to form a plurality of fourth recess regions. The plurality of fourth recess regions may overlap the plurality of dummy patterns 133D′, and may be formed in a different shape from the plurality of dummy patterns 133D′. Subsequently, the plurality of fourth recess regions may be filled with a conductive material, and the conductive material may be separated into a plurality of first upper dummy patterns 143D′ through the planarization process. In an embodiment, the plurality of first upper dummy patterns 143D′ may be used as the dishing inhibiting pattern.

Referring to FIG. 13B, the fifth insulating layer 151 may be formed to cover the plurality of first upper dummy patterns 143D′. Thereafter, part of the fifth insulating layer 151 may be etched to form a plurality of fifth recess regions. The plurality of fifth recess regions may overlap the plurality of first upper dummy patterns 143D′, and may be formed in a different shape from the plurality of first upper dummy patterns 143D′. Subsequently, the plurality of fifth recess regions may be filled with a conductive material, and the conductive material may be separated into a plurality of second upper dummy patterns 153D′ through the planarization process. In an embodiment, the plurality of second upper dummy patterns 153D′ may be used as the dishing inhibiting pattern.

The semiconductor device shown in FIG. 8 may be provided using the processes described with reference to FIGS. 13A and 13B.

According to an embodiment of the present disclosure, because alignment between patterns in a chip region are determined using an overlay mark including a plurality of lower vernier patterns and then a plurality of dummy patterns are formed, measurement signals from the lower vernier patterns can be avoided from interference from a plurality of dummy patterns. Thus, in an embodiment, the accuracy of alignment monitoring can be enhanced and the stability of the manufacturing process of a semiconductor device can be ensured.

According to an embodiment of the present disclosure, because a plurality of dummy patterns overlap a plurality of lower vernier patterns, the arrangement efficiency of patterns disposed in a scribe region can be improved, and the integration degree of the patterns disposed in the scribe region can be increased.

According to an embodiment of the present disclosure, because a plurality of dummy patterns can be used as a dishing inhibiting structure and overlap a plurality of lower vernier patterns, a planar area occupied by the patterns disposed in a scribe lane region can be reduced while ensuring the stability of a manufacturing process.

What is claimed is:

1. A semiconductor device, comprising:
a wafer including a chip region and a scribe lane region surrounding the chip region, a surface of the wafer extending in a plane in a first direction and a second direction;
a first insulating layer, a second insulating layer, and a third insulating layer sequentially stacked in a third direction over the surface of the wafer;
a first overlay mark including a plurality of lower vernier patterns disposed in the first insulating layer and the second insulating layer, and overlapping the scribe lane region of the wafer in the third direction; and
a plurality of dummy patterns disposed in the third insulating layer, and overlapping the scribe lane region of the wafer in the third direction,
wherein each of the plurality of dummy patterns is formed with a first area measured in the first and second directions,
wherein each of the plurality of lower vernier patterns is formed with a second area measured in the first and second directions, and
wherein the first area of each of the plurality of dummy patterns is smaller than the second area of each of the plurality of lower vernier patterns.

2. The semiconductor device according to claim 1, wherein the plurality of lower vernier patterns comprise:
a plurality of first lower vernier patterns disposed in the first insulating layer; and
a plurality of second lower vernier patterns disposed in the second insulating layer and disposed in regions within the second insulating layer which do not overlap with the plurality of first lower vernier patterns in the third direction.

3. The semiconductor device according to claim 2, further comprising:
a first contact plug disposed in the first insulating layer, and overlapping the chip region of the wafer in the third direction;
a conductive line disposed in the second insulating layer, and overlapping the chip region of the wafer in the third direction; and
a second contact plug disposed in the third insulating layer, and overlapping the chip region of the wafer in the third direction,
wherein the plurality of first lower vernier patterns comprise substantially the same conductive material as the first contact plug,
wherein the plurality of second lower vernier patterns comprise substantially the same conductive material as the conductive line, and
wherein the plurality of dummy patterns comprise substantially the same conductive material as the second contact plug.

4. The semiconductor device according to claim 2, wherein the plurality of dummy patterns overlap the plurality of first lower vernier patterns and the plurality of second lower vernier patterns in the third direction.

5. The semiconductor device according to claim 1, further comprising:
a fourth insulating layer and a fifth insulating layer sequentially stacked over the third insulating layer in the third direction; and
a second overlay mark including a plurality of upper vernier patterns disposed in the fourth insulating layer and the fifth insulating layer, and overlapping the scribe lane region of the wafer in the third direction,
wherein each of the plurality of upper vernier patterns is formed with a third area measured in the first and second directions, and
wherein the first area of each of the plurality of dummy patterns is smaller than the third area of each of the plurality of upper vernier patterns.

6. The semiconductor device according to claim 5, wherein the plurality of upper vernier patterns overlap the plurality of lower vernier patterns in the third direction.

7. The semiconductor device according to claim 5, wherein the plurality of upper vernier patterns comprise:
a plurality of first upper vernier patterns disposed in the fourth insulating layer; and
a plurality of second upper vernier patterns disposed in the fourth insulating layer and disposed in regions within the fourth insulating layer which do not overlap with the plurality of first upper vernier patterns in the third direction.

8. The semiconductor device according to claim 7, further comprising:
a conductive line disposed in the fourth insulating layer, and overlapping the chip region of the wafer in the third direction; and
a contact plug disposed in the fifth insulating layer, and overlapping the chip region in the third direction,
wherein the plurality of first upper vernier patterns comprise substantially the same conductive material as the conductive line, and
wherein the plurality of second upper vernier patterns comprise substantially the same conductive material as the contact plug.

9. The semiconductor device according to claim 7, wherein the plurality of first upper vernier patterns and the plurality of second upper vernier patterns overlap the plurality of dummy patterns in the third direction.

10. The semiconductor device according to claim 1, wherein the plurality of dummy patterns form a dishing inhibiting structure.

11. A semiconductor device, comprising:
a wafer including a chip region and a scribe lane region surrounding the chip region, a surface of the wafer extending in a plane in a first direction and a second direction;
a first insulating layer, a second insulating layer, a third insulating layer, a fourth insulating layer, and a fifth insulating layer sequentially stacked in a third direction over the surface of the wafer;
a plurality of dummy patterns disposed in the third insulating layer, and overlapping the scribe lane region in the third direction; and
an overlay mark overlapping the scribe lane region of the wafer in the third direction,
wherein the overlay mark is not disposed in a region within each of the fourth insulating layer and the fifth insulating layer overlapping the plurality of dummy patterns in the third direction, and
wherein the overlay mark comprises a plurality of lower vernier patterns disposed in the first insulating layer and the second insulating layer.

12. The semiconductor device according to claim 11, wherein the plurality of lower vernier patterns comprise:
a plurality of first lower vernier patterns disposed in the first insulating layer; and
a plurality of second lower vernier patterns disposed in the second insulating layer and disposed in regions within the second insulating layer which do not overlap with the plurality of first lower vernier patterns in the third direction.

13. The semiconductor device according to claim 12, further comprising:
a first contact plug disposed in the first insulating layer, and overlapping the chip region of the wafer in the third direction;
a conductive line disposed in the second insulating layer, and overlapping the chip region of the wafer in the third direction; and
a second contact plug disposed in the third insulating layer, and overlapping the chip region of the wafer in the third direction,
wherein the plurality of first lower vernier patterns comprise substantially the same conductive material as the first contact plug,
wherein the plurality of second lower vernier patterns comprise substantially the same conductive material as the conductive line, and
wherein the plurality of dummy patterns comprise substantially the same conductive material as the second contact plug.

14. The semiconductor device according to claim 12, wherein the plurality of dummy patterns overlap the plurality of first lower vernier patterns and the plurality of second lower vernier patterns in the third direction.

15. The semiconductor device according to claim 11, wherein the plurality of dummy patterns are covered with the fourth insulating layer and the fifth insulating layer.

16. The semiconductor device according to claim 11, further comprising:
a conductive line disposed in the fourth insulating layer, and overlapping the chip region of the wafer in the third direction; and
a contact plug disposed in the fifth insulating layer, and overlapping the chip region of the wafer in the third direction.

17. The semiconductor device according to claim 16, further comprising:
a plurality of first upper dummy patterns disposed in a region of the fourth insulating layer overlapping the overlay mark in the third direction, and including substantially the same conductive material as the conductive line.

18. The semiconductor device according to claim 16, further comprising:
a plurality of first upper dummy patterns disposed in a region of the fifth insulating layer overlapping the overlay mark in the third direction, and including substantially the same conductive material as the contact plug.

19. The semiconductor device according to claim 11, wherein the plurality of dummy patterns form a dishing inhibiting structure.

20. A semiconductor device comprising:
a wafer including a chip region and a scribe lane region surrounding the chip region, a surface of the wafer extending in a plane in a first direction and a second direction;
a first insulating layer, a second insulating layer, and a third insulating layer sequentially stacked in a third direction over the surface of the wafer;
an overlay mark including a plurality of lower vernier patterns disposed in the first insulating layer and the second insulating layer, and overlapping the scribe lane region of the wafer in the third direction; and
a dishing inhibiting structure including a plurality of dummy patterns disposed in the third insulating layer, the dummy patterns overlapping the scribe lane region of the wafer in the third direction,
wherein the plurality of dummy patterns overlap the plurality of lower vernier patterns in the third direction.
